(19) United States
(12) Patent Application Publication
(10) Pub. No.: US 2015/0228814 A1
(43) Pub. Date: Aug. 13, 2015

(54) SOLAR CELL

(71) Applicant: Panasonic Intellectual Property Management Co., Ltd., Osaka (JP)

(72) Inventors: Kenta MATSUYAMA, Osaka (JP); Takayoshi SONE, Osaka (JP); Kazunori FUJITA, Gifu (JP)

(21) Appl. No.: 14/692,016

(22) Filed: Apr. 21, 2015

Related U.S. Application Data
(63) Continuation of application No. PCT/JP2013/006259, filed on Oct. 23, 2013.

(30) Foreign Application Priority Data
Oct. 23, 2012 (JP) 2012-233821

(51) Int. Cl. H01L 31/0236; H01L 31/0376; H01L 31/0224

(52) U.S. Cl. CPC H01L 31/02363; H01L 31/022475; H01L 31/03762

(57) ABSTRACT

A solar cell is provided with: a semiconductor substrate upon which a textured structure is formed; and transparent conductive layers that are formed on the substrate, the thicknesses of which are substantially fixed in a trough part of the textured structure.

### CROSS-REFERENCE TO RELATED APPLICATIONS

The present application is a continuation under 35 U.S.C. §120 of PCT/JP2013/006259, filed on Oct. 23, 2013, which is incorporated herein by reference and which claimed priority under 35 U.S.C. §119 to Japanese Patent Application No. 2012-233821 filed on Oct. 23, 2012, the entire content of which is also incorporated herein by reference.

### TECHNICAL FIELD

The present invention relates to a solar cell.

### BACKGROUND ART

Patent Document 1 discloses a solar cell including a transparent conductive layer on a semiconductor substrate upon which is formed a textured structure that is an uneven surface structure to reduce reflection of light.

### CITATION LIST

### Patent Literature

### Patent Document 1

International Publication No. WO98/43304

### SUMMARY OF INVENTION

### Technical Problem

In the conventional techniques including the solar cell of aforementioned Patent Document 1, as illustrated in FIG. 6, the thickness of a transparent conductive layer 101 in a trough part 100 of the textured structure is not fixed, and the thickness of the transparent conductive layer 101 increases toward a deepest portion 100p of the trough part 100. For improvement in photoelectric conversion characteristics of a solar cell, reducing unevenness in thickness of a transparent conductive layer in a trough part is preferable.

### Solution to Problem

A solar cell of the present invention is provided with a photoelectrical converter including a semiconductor substrate upon which a textured structure is formed, and transparent conductive layers that are formed on the photoelectrical converter, the thicknesses of which are substantially fixed in a trough part of the textured structure.

### Advantageous Effect of Invention

The present invention provides a solar cell with excellent photoelectric conversion characteristics.

### BRIEF DESCRIPTION OF DRAWINGS

FIG. 1 is a plan view of a solar cell serving as an example of an embodiment of the present invention, as viewed from a light-receiving surface side.

FIG. 2 is a partial sectional view taken along line A-A in FIG. 1.

FIG. 3 is an enlarged view of a trough part of a textured structure in FIG. 2.

FIG. 4 is an enlarged view of a tip section of the textured structure in FIG. 2.

FIG. 5 illustrates a textured structure (trough part and tip section) serving as an example of the embodiment of the present invention.

FIG. 6 is a cross sectional view of an enlarged trough part of a conventional textured structure.

### DESCRIPTION OF EMBODIMENTS

Detailed descriptions will be given below of a solar cell 10 as an example of an embodiment of the present invention with reference to the drawings. However, application of the present invention is not limited to the embodiments. The drawings which are referred to in the embodiments are schematic views. The specific sizes or ratios of components illustrated in the drawings may differ from real ones. Such specific sizes, ratios, etc. should be determined by considering the following descriptions.

The expression “a second member (e.g., transparent conductive layer) is formed on a first member (e.g., photoelectric converter)” herein does not mean only a case where the first member is in direct contact with the second member, unless otherwise noted. That is, the expression includes a case where another element exists between the first and second members.

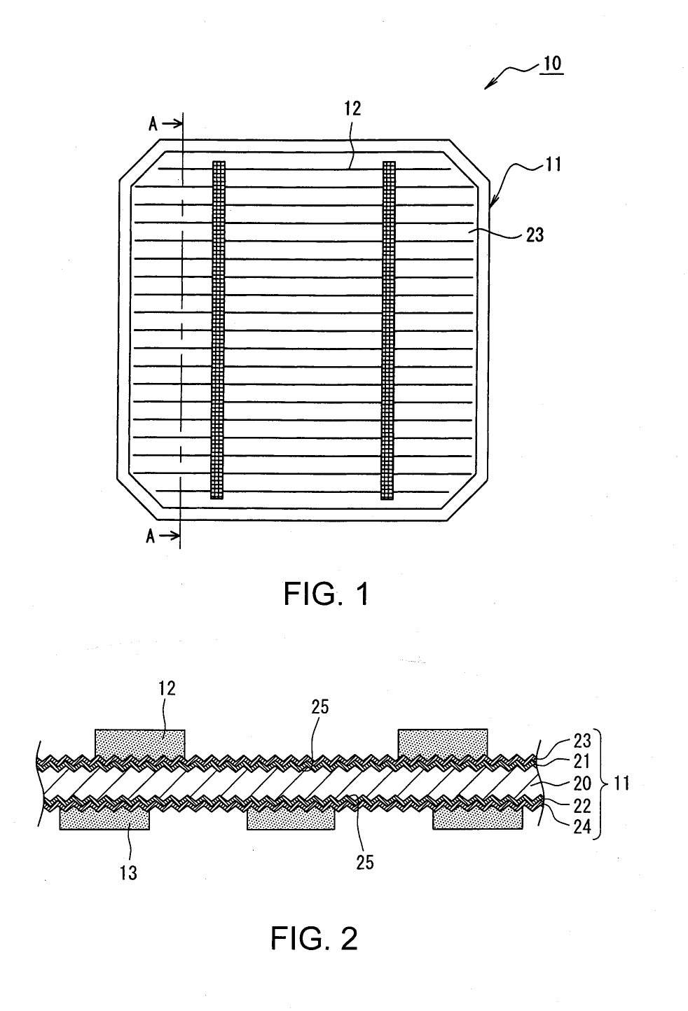

FIG. 1 is a plan view of the solar cell 10, as viewed from a light-receiving surface side. FIG. 2, which is a partial sectional view taken along line A-A in FIG. 1, illustrates a cross section of the solar cell 10 cut in a thickness direction along a direction orthogonal to finger portions of a first electrode 12 and a second electrode 13.

The solar cell 10 includes a photoelectric converter 11 that generates a carrier on reception of solar light; the first electrode 12, which is a light-receiving electrode formed on a light-receiving surface of the photoelectric converter 11; and the second electrode 13, which is a rear electrode formed on a rear face of the photoelectric converter 11. In the solar cell 10, a carrier generated by the photoelectric converter 11 is collected by the first electrode 12 and the second electrode 13.

The “light-receiving surface” means a surface to which light mainly enters from the outside of the solar cell 10. For example, more than 50% to 100% of light entering the solar cell 10 enters from the light-receiving surface side. The “rear surface” means a surface opposite the light-receiving surface. Hereinafter, the light-receiving surface and the rear surface are collectively referred to as “main surface.”

The photoelectric converter 11 includes a semiconductor substrate 20 (hereinafter referred to as “substrate 20”), an amorphous semiconductor layer 21 on the light-receiving surface side of the substrate 20, and an amorphous semiconductor layer 22 on the rear surface side of the substrate 20. Further, the photoelectric converter 11 has a transparent conductive layer 23 on the amorphous semiconductor layer 21 and a transparent conductive layer 24 on the amorphous semiconductor layer 22.

The substrate 20 is made of a semiconductor material, e.g., crystalline silicon (c-Si), or polysilicon (poly-Si). Of such semiconductor materials, single-crystal silicon is preferable, and n-type single-crystal silicon is particularly preferable. A textured structure 25 that is an uneven surface structure is formed on the substrate 20. It may be the case that the textured structure 25 is formed only on the light-receiving surface of the substrate 20. Preferably, however, the textured structure 25 is formed on both the light-receiving surface and the rear surface. Details of the textured structure 25 will be given later.

The amorphous semiconductor layer 21 has, for example, a multilayer structure in which an i-type amorphous silicon layer and a p-type amorphous silicon layer are formed in order from the substrate 20 side. The amorphous semiconductor layer 22 has, for example, a multilayer structure in which an i-type amorphous silicon layer and an n-type amorphous silicon layer are formed in order from the substrate 20 side. The amorphous semiconductor layers 21 and 22 are formed on the respective textured structures 25. The photoelectric converter 11 may have a structure in which an i-type amorphous silicon layer and an n-type amorphous silicon layer are formed in order on the light-receiving surface of the substrate 20, and an i-type amorphous silicon layer and a p-type amorphous silicon layer are formed in order on the rear surface of the substrate 20.

The transparent conductive layers 23 and 24 may be formed of a transparent conductive oxide that is obtained by doping metal oxide, e.g., indium oxide (In₂O₃) or zinc oxide (ZnO) with e.g., tin (Sn) or antimony (Sb). The transparent conductive layers 23 and 24 are formed on the respective textured structures 25 via the amorphous semiconductor layers 21 and 22, respectively. The transparent conductive layers 23 and 24 are formed on regions other than edges on the amorphous semiconductor layers, from the viewpoint of productivity.

The first electrode 12 is a metal electrode that collects carriers via the transparent conductive layer 23. The first electrode 12 includes multiple (for example, 50) finger parts which are filled in trough parts 27 of the textured structure 25 and formed on the transparent conductive layer 23, and multiple (for example, two) bus bar parts which extend in a direction intersecting with the finger parts. The finger parts are thin-line shaped electrodes which are formed in a wide range on the transparent conductive layer 23. The bus bar parts are electrodes that collect carriers from the finger parts. For example, to the bus bar part, which is thicker than the finger part, a wiring material is connected at the time of modularization of the solar cell 10.

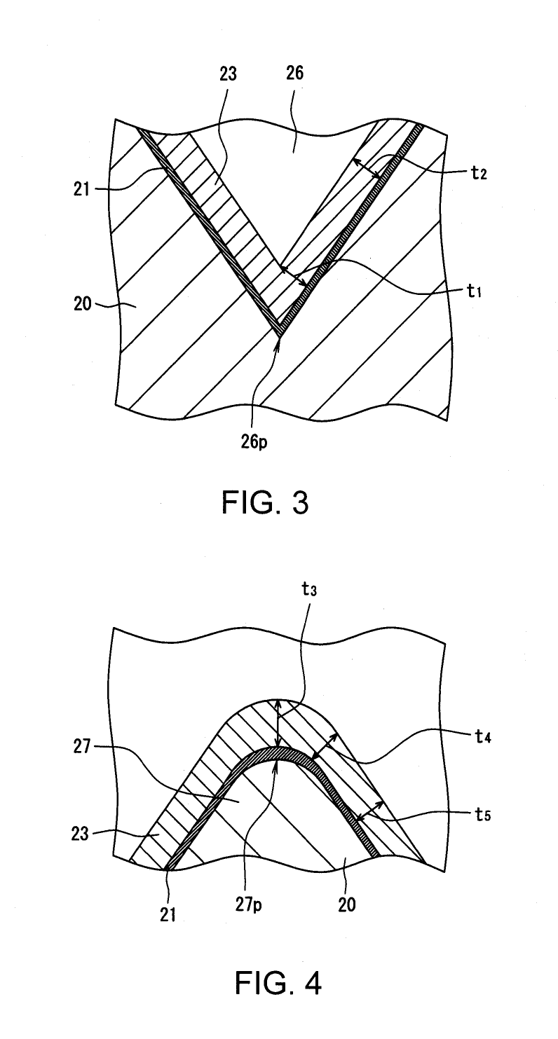

The first electrode 12 has a configuration in which a conductive filler, e.g., silver (Ag), is dispersed in a binder resin, or a configuration including metal only, such as nickel (Ni), copper (Cu) and silver (Ag). For example, the former is formed by screen printing with conductive paste, while the latter is formed by electrolytic plating, vapor deposition, or sputtering. The first electrode 12 fills in the trough parts 26 of the textured structure 25 (see FIG. 3, which will be described below). The first electrode 12 is formed on the textured structure 25 via e.g., the transparent conductive layer 23.

The second electrode 13, similar to the first electrode 12, preferably includes multiple finger parts which are filled in the trough parts 26 of the textured structure 25 and formed on the transparent conductive layer 24, and multiple bus bar parts which extend to intersect with the finger parts. However, the second electrode 13 preferably has a larger area than the first electrode 12, and the number of the finger parts of the second electrode 13 (for example, 250 finger parts) is, for example, larger than that of the first electrode 12. The second electrode 13 may be a metal layer formed on substantially the entire region on the transparent conductive layer 24.

FIGS. 3 and 4 are enlarged cross sectional views of the textured structure 25 on the light-receiving surface side, and the transparent conductive layer 23 and the like on the textured structure 25. FIG. 3 illustrates the trough part 26 of the textured structure 25. FIG. 4 illustrates a tip section 27 of the textured structure 25. The structure of the light-receiving surface side is exemplified herein. The structure of the rear surface side is similar to that of the light-receiving surface side.

The textured structure 25 has an uneven surface structure serving to prevent light from being reflected by a surface and to increase a light absorption amount of the photoelectric converter 11. The structure includes many substantially pyramid shaped convex parts. Two adjacent convex parts are in contact with each other. Some of the convex parts may have such a distorted shape that does not resemble a pyramid shape. However, at least half of the convex parts have a substantially pyramid shape which includes flat slopes with an area decreasing toward an upper end and includes a tip end 27p which is a peak at the upper end.

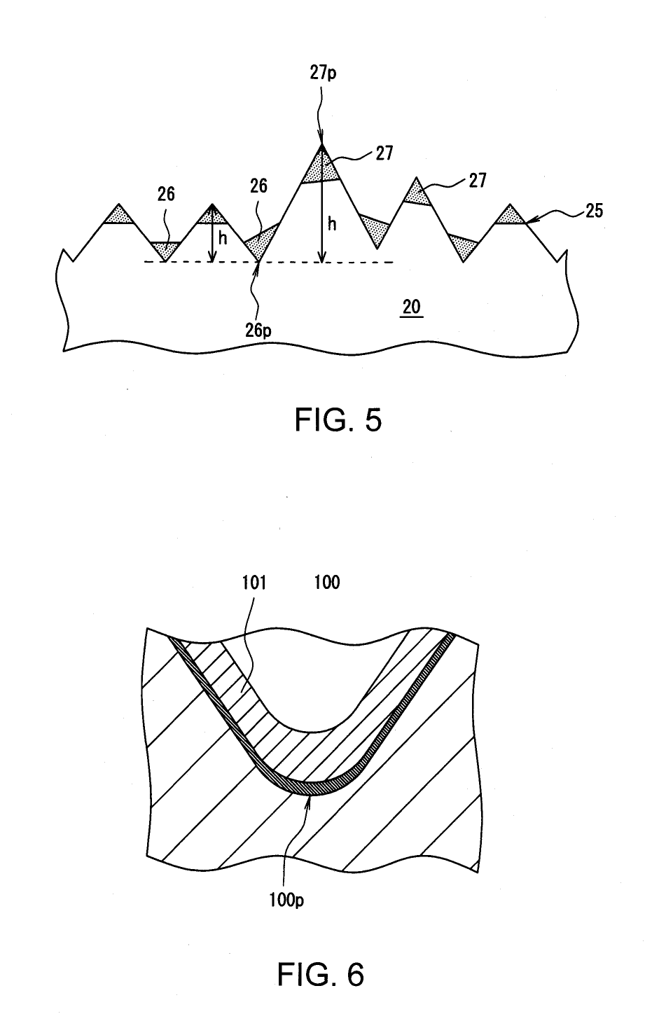

The trough part 26 of the textured structure 25 herein means a concave part between adjacent multiple convex parts. More specifically, as illustrated in FIG. 5, the trough part 26 is defined as a region from a trough bottom 26p, which is the deepest point of the concave part, to a height of one-third a height h of the convex part which forms the concave part. In FIG. 5, hatching is omitted in the amorphous semiconductor layer 21, the transparent conductive layer 23, and the substrate 20, for clarification of the drawing. The height h of the convex part indicates a length from the tip end 27p, which is the highest point of the convex part, to the trough bottom 26p, which is the deepest point among the surrounding trough bottoms 26p, along the thickness direction of the substrate 20. That is, the height h of the convex part corresponds to the depth of the concave part. The tip section 27 of the textured structure 25 is defined as a region from the tip end 27p to a height of one-third the height h of the convex part.

The textured structure 25 has a size (hereinafter, may be referred to as “Tx size”) of approximately 1 to 15 μm, preferably approximately 1.5 to 5 μm. The “Tx size,” which means a size when a main surface of the substrate 20 is planarly viewed, can be measured with a scanning electron microscope (SEM) or a laser microscope. Although the Tx size is not limitedly defined, the Tx size is defined, in the following description, as one of sides of the convex part when each convex part on the textured structure 25 is assumed to be a square shape when the main surface of the substrate 20 is viewed in plane. The Tx size means a median which is obtained by measuring approximately 200 convex parts.

The height h of the convex part of the textured structure 25 is, for example, 1 to 10 μm, and preferably, 1.5 to 5 μm. The amorphous semiconductor layer 21 and the transparent conductive layer 23 each have a thickness of approximately several nm to several hundred nm, as described later. Thus, the textured structure 25 also appears on thin-film layers of the amorphous semiconductor layer 21 and the transparent conductive layer 23. In other words, the amorphous semiconductor layer 21 and the transparent conductive layer 23 are formed depending on the shape of the textured structure 25.

The trough part 26 of the textured structure 25 is V-shaped. The trough bottom 26p is sharp. That is, the flat slopes of the adjacent convex parts are directly connected with each other to form the trough part 26. The trough bottom 26p includes no flat portion along a surface direction of the main surface (a direction orthogonal to the thickness direction of the substrate 20). The textured structure 25 of the trough bottom 26p has an extremely small curvature radius (hereinafter, referred to as “curvature radius r₂₆”), which is, for example, less than 10 nm. The curvature radius r₂₆ is smaller than the thickness of the transparent conductive layer 23, and further, smaller than the thickness of the amorphous semiconductor layer 21. The V-shaped trough part 26 and the sharp trough bottom 26p cause efficient multi-reflection of incident light at the trough part 26, and thus, the light absorption efficiency of the photoelectric converter 11 can be improved.

In the trough part 26, the thickness of the transparent conductive layer 23 is substantially fixed. The meaning of the expression “substantially fixed” includes a range considered as practically equivalent. Specifically, the expression means the difference between the maximum thickness and the minimum thickness is 10% or less. Such difference is preferably 5% or less. That is, the thickness t₁ in the vicinity of the trough bottom 26p is equivalent to the thickness t₂ in the upper part of the trough part 26, and the difference between the thicknesses t₁ and t₂ is 10% or less. The thickness of the transparent conductive layer 23 is a length from the upper end surface of the transparent conductive layer 23 to the slope of the convex part; i.e., a length along a direction orthogonal to the upper end surface (the same applies to the amorphous semiconductor layers). The thickness of the transparent conductive layer 23 can be measured through cross-section observation with an SEM.

The thickness of the transparent conductive layer 23 is preferably approximately 30 to 200 nm, and particularly preferably approximately 40 to 100 nm. If the thickness t₁ is 70 nm, for example, the thickness t₂ is also 70 nm, which is the same as the thickness t₁, or the difference between the thicknesses t₁ and t₂, if any, is approximately ±7 nm from 70 nm.

In the trough part 26, the thickness of the amorphous semiconductor layer 21 is also substantially fixed. If the amorphous semiconductor layer 21 formed on the trough part 26 has a maximum thickness and a minimum thickness, the difference between the thicknesses is 10% or less, preferably 5% or less. The thickness of the amorphous semiconductor layer 21 is preferably approximately 1 to 20 nm, particularly preferably approximately 5 to 15 nm.

In the tip sections 27 of the textured structure 25, more than half of multiple convex parts are rounded with no sharp tip end 27p. That is, a sectional shape of the tip end 27p is substantially an arc. The textured structure 25 of the tip end 27p has a curvature radius (hereinafter, referred to as “curvature radius r₂₇”) larger than the curvature radius r₂₆, of 50 to 500 nm, for example. The curvature radius r₂₇ is preferably more than five times, more preferably more than ten times, and particularly preferably more than 50 times larger than the curvature radius r₂₆. The curvature radius r₂₇ is larger than the thickness of the transparent conductive layer 23, and further, larger than that of the amorphous semiconductor layer 21. The rounded tip section 27 prevents the tip section 27 from being damaged when the solar cell 10 is manufactured or used.

The thickness of the transparent conductive layer 23 may be substantially fixed not only in the trough part 26, but also in the whole area on the textured structure 25 including the tip section 27 of the convex part. However, the thickness of the transparent conductive layer 23 is preferably thicker in the vicinity of the tip end 27p of the convex part. In other words, the thickness of the transparent conductive layer 23 is preferably substantially fixed over the whole area on the textured structure 25 excluding the vicinity of the tip end 27p of the convex part. The same applies to the amorphous semiconductor layer 21.

That is, the thickness t₃ of the transparent conductive layer 23 at the tip section 27 is preferably larger than the thickness t₁ or the thickness t₂ in the trough part 26. For example, the thickness of the transparent conductive layer 23 in the tip section 27 preferably increases toward the tip end 27p (t₃>t₄>t₅), and the transparent conductive layer 23 preferably has a maximum thickness at the tip end 27p. In the amorphous semiconductor layer 21, which also provides the same characteristics as the transparent conductive layer 23, the thickness in the tip section 27 is larger than that in the trough part 26.

The textured structure 25 may be formed by etching the substrate 20 with etching liquid. When the substrate 20 is a single-crystal silicon substrate with a (100) plane, examples of a preferred type of etching liquid include an alkaline solution, e.g., a solution of sodium hydroxide (NaOH), and a solution of potassium hydroxide (KOH). The concentration of such alkaline solution is preferably 1 to 10 wt. %, approximately. A solvent, which is an aqueous solvent containing water as a main component, includes approximately 1 to 10 wt. % of an additive, for example. Examples of the additive include an alcohol solvent, e.g., isopropyl alcohol, cyclohexanediol, or octanol, and an organic acid, e.g., 4-propylbenzoic acid, 4-t-butylbenzoic acid, 4-n-butylbenzoic acid, 4-pentylbenzoic acid, 4-butoxybenzonic acid, 4-n-octylbenzenesulfonic acid, caprylic acid, or lauric acid.

If the single-crystal silicon substrate with the (100) plane is immersed in an alkaline solution, anisotropic etching is performed along a (111) plane so that many convex parts having substantially pyramid shapes are formed on the main surface of the substrate 20. By changing the substrate 20 to be used, the concentration or the temperature of the etching liquid, the composition ratio, the processing time period, or the like, the Tx size can be adjusted. The textured structure 25 may be formed with use of etching gas.

A cleaning process of the substrate 20 may be executed after formation of the textured structure 25. The cleaning process is executed preferably without use of chemical liquid causing further etching of the substrate 20, e.g., a mixed solution (fluonitric acid) of hydrofluoric acid (HF) and nitric acid (HNO₃).

The amorphous semiconductor layers 21 and 22 may be formed by chemical vapor deposition (CVD) or sputtering. To form an i-type amorphous silicon layer by CVD, there is used raw material gas, for example, obtained by diluting silane (SiH₄) with hydrogen (H₂). To form a p-type amorphous silicon layer, raw material gas obtained by adding diborane (B₂H₆) to silane and diluting the resultant mixture with hydrogen (H₂) may be used. To form an n-type amorphous silicon layer, raw material gas obtained by adding phosphine (PH₃) to silane and diluting the resultant mixture with hydrogen (H₂) may be used. The transparent conductive layers 23 and 24 may also be formed by CVD or sputtering. The film formation by CVD is performed at the temperature of approximately 200 to 300° c. Such heat crystallizes TCO to improve the conductivity.

As described above, in the solar cell 10, the respective thicknesses of the transparent conductive layers 23 and 24 are substantially fixed in the trough part 26 of the textured structure 25. In the trough part 26, the respective thicknesses of the amorphous semiconductor layers 21 and 22 are also substantially fixed. Accordingly, a strict optical or electric design for suitable photoelectric conversion characteristics is possible. Therefore, the solar cell 10 allows improvement of the photoelectric conversion characteristics.

The area of the trough part 26 on the main surface of the solar cell 10 is larger than that of the tip section 27. The structure of the trough part 26 largely affects the photoelectric conversion characteristics. Therefore, it is important to reduce unevenness in thicknesses of the transparent conductive layers 23 and 24 and the like in the trough part 26.

The structure of the tip section 27 has a smaller effect on the photoelectric conversion characteristics than does the trough part 26. Thus, in the tip section 27, the thicknesses of the transparent conductive layers 23 and 24 are increased to protect the tip section 27 so that damage to the tip section 27 can be prevented when the solar cell 10 is manufactured or used.

### REFERENCE SIGNS LIST

10 solar cell, 11 photoelectric converter, 12 first electrode, 13 second electrode, 20 substrate, 21, 22 amorphous semiconductor layer, 23, 24 transparent conductive layer, 25 textured structure, 26 trough part, 26p trough bottom, 27 tip section, 27p tip end.

1. A solar cell provided with:
a semiconductor substrate including a textured structure; and
a transparent conductive layer that is formed on the semiconductor substrate, a thickness of the transparent conductive layer being substantially fixed in a trough part of the textured structure.

2. The solar cell according to claim 1, wherein the thickness of the transparent conductive layer in a tip section of the textured structure is larger than the thickness of the transparent conductive layer in the trough part.

3. The solar cell according to claim 1, wherein a curvature radius of the trough part is smaller than a curvature radius of the tip section of the textured structure.

4. The solar cell according to claim 1, further comprising an amorphous semiconductor layer that is formed on the semiconductor substrate, wherein a thickness of the amorphous semiconductor layer is substantially fixed in the trough part.
